(19) United States
(12) Patent Application Publication
(10) Pub. No.: US 2020/0091078 A1
(43) Pub. Date: Mar. 19, 2020

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroaki TAKAHASHI, Oita Oita (JP); Shoichi SAKAGUCHI, Oita Oita (JP)

(21) Appl. No.: 16/286,308

(22) Filed: Feb. 26, 2019

(30) Foreign Application Priority Data
Sep. 19, 2018 (JP) 2018-175442

(51) Int. Cl. H01L 23/532; H01L 23/31; H01L 23/29; H01L 21/56

(52) U.S. Cl. CPC H01L 23/53228; H01L 23/53295; H01L 21/56; H01L 23/293; H01L 23/3114; H01L 23/3121

(57) ABSTRACT

A semiconductor device includes a semiconductor substrate, a multilayer wiring layer on the semiconductor substrate, an insulation layer above the multilayer wiring layer, first and second metal wirings on the insulation layer, and a resin film that covers the insulation layer and the first second metal wirings. The resin film has a thickness about three times a thickness of the first and second metal wirings in a direction perpendicular to the semiconductor substrate, and a thickness of each of the first and second metal wirings is greater than a thickness of a wiring included in the multilayer wiring layer.

### CROSS-REFERENCE TO RELATED APPLICATIONS

This application is based upon and claims the benefit of priority from Japanese Patent Application No. 2018-175442, filed Sep. 19, 2018, the entire contents of which are incorporated herein by reference.

### FIELD

Embodiments described herein relate generally to a semiconductor device.

### BACKGROUND

A wafer level chip size package (WL-CSP) is a known technology for packaging semiconductor devices at the wafer level. In the WL-CSP, redistribution layers, protective resin films, and solder bumps are formed on electrode pads of the semiconductor devices during a wafer process, and then dicing is performed to divide the wafer into the individual semiconductor devices to complete the packages.

In the redistribution layer, a thick metal wiring is used in order to reduce resistance. However, a crack may occur in the protective resin film on an upper layer of the metal wiring due to stress generated by heat treatment after formation of the thick metal wiring, which decreases reliability of the semiconductor device.

### DESCRIPTION OF THE DRAWINGS

FIG. 1 is a schematic cross-sectional view of a semiconductor device of an embodiment.

FIGS. 2-5 illustrate a cross-section of the semiconductor device of the embodiment during manufacturing.

FIG. 6 is a schematic cross-sectional view of a semiconductor device of a comparative example.

FIGS. 7A and 7B are photographs of cracks in the semiconductor device of the comparative example.

FIG. 8 is a diagram illustrating operation and effects of the semiconductor device of the embodiment.

### DETAILED DESCRIPTION

An embodiment provides a semiconductor device in which occurrence of a crack in a resin film is prevented.

In general, according to an embodiment, a semiconductor device includes a semiconductor substrate, a multilayer wiring layer on the semiconductor substrate, an insulation layer above the multilayer wiring layer, first and second metal wirings on the insulation layer, and a resin film that covers the insulation layer and the first second metal wirings. The resin film has a thickness about three times a thickness of the first and second metal wirings in a direction perpendicular to the semiconductor substrate, and a thickness of each of the first and second metal wirings is greater than a thickness of a wiring included in the multilayer wiring layer.

In the specification, the same or similar elements are denoted by the same reference signs, and redundant descriptions thereof may be omitted.

In the specification, in order to illustrate positional relationships between components or the like, the upper direction of the drawings may be referred to as “upper”, and the lower direction of the drawings may be referred to as “lower”. Concepts of “upper” and “lower” in the specification are not necessarily terms showing relationships with the gravity direction.

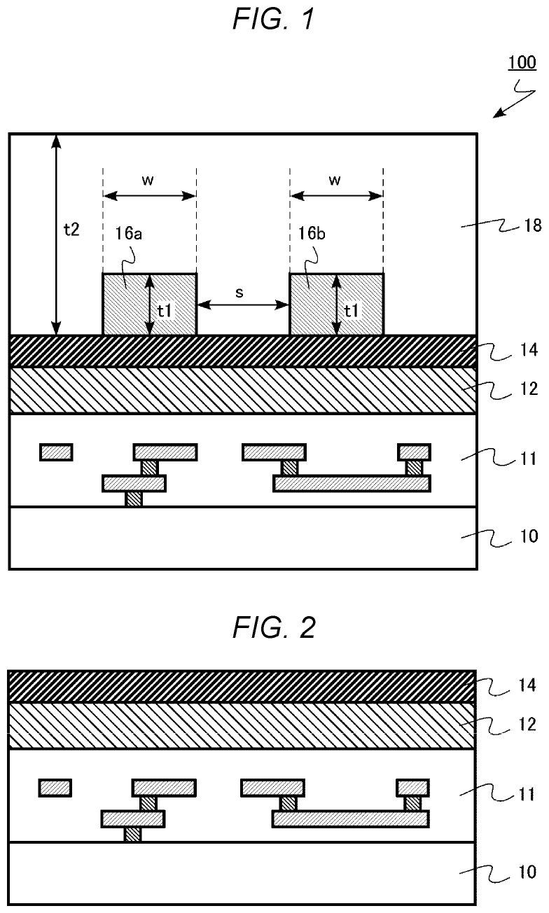

FIG. 1 is a schematic cross-sectional view of the semiconductor device of the embodiment. A semiconductor device 100 of the embodiment includes a redistribution layer for WL-CSP.

The semiconductor device 100 of the embodiment includes a silicon substrate 10, a multilayer wiring layer 11, a silicon oxide layer 12, a silicon nitride layer 14, a first copper wiring 16a, a second copper wiring 16b and a polyimide film 18.

The silicon substrate 10 is a single-crystal silicon substrate. For example, a semiconductor element, such as a transistor or a diode (not illustrated), may be formed on the silicon substrate 10.

The multilayer wiring layer 11 is provided on the silicon substrate 10. The multilayer wiring layer 11 includes an interlayer insulation film and a wiring. The multilayer wiring layer 11 and the semiconductor element formed on the silicon substrate 10 make up an integrated circuit having a specific function.

The silicon oxide layer 12 is provided on the multilayer wiring layer 11. The silicon oxide layer 12 is, for example, a passivation film that protects the silicon substrate 10 and the multilayer wiring layer 11.

The silicon nitride layer 14 is provided on the silicon oxide layer 12. The silicon nitride layer 14 is, for example, a passivation film that protects the silicon substrate 10 and the multilayer wiring layer 11. The passivation film has a stacked structure including the silicon oxide layer 12 and the silicon nitride layer 14.

The first copper wiring 16a and the second copper wiring 16b are provided on the silicon nitride layer 14 and extend, for example, in parallel. The first copper wiring 16a and the second copper wiring 16b are made of, for example, pure copper or a copper alloy.

The first copper wiring 16a and the second copper wiring 16b are redistribution layers for WL-CSP and are connected to, for example, an electrode pad (not illustrated) provided below the silicon oxide layer 12. The first copper wiring 16a and the second copper wiring 16b electrically connect, for example, the electrode pad with a terminal for bump connection that is provided on the silicon nitride layer 14.

The film thickness t1 of the first copper wiring 16a and the second copper wiring 16b is, for example, equal to or more than 5 μm and equal to or less than 20 μm. The width w of the first copper wiring 16a and the second copper wiring 16b is, for example, equal to or more than 100 μm and equal to or less than 300 μm. The interval s between the first copper wiring 16a and the second copper wiring 16b is, for example, equal to or more than 5 μm and equal to or less than 20 μm. In addition, the thickness of each of the first and second copper wirings 16a and 16b is greater than the thickness of the wiring included in the multilayer wiring layer 11. In one embodiment, the thickness of each of the first and second copper wirings 16a and 16b is greater than the thickness of the wiring included in the multilayer wiring layer 11 by 2 times.

The polyimide film 18 is provided on the first copper wiring 16a and the second copper wiring 16b and is in contact therewith. The polyimide film 18 is a protective resin film of the first copper wiring 16a and the second copper wiring 16b. The film thickness t2 of the polyimide film 18 is, for example, equal to or more than 30 μm and equal to or less than 60 μm.

The film thickness t2 of the polyimide film 18 is approximately equal to or more than three times the film thickness t1 of the first copper wiring 16a and of the second copper wiring 16b.

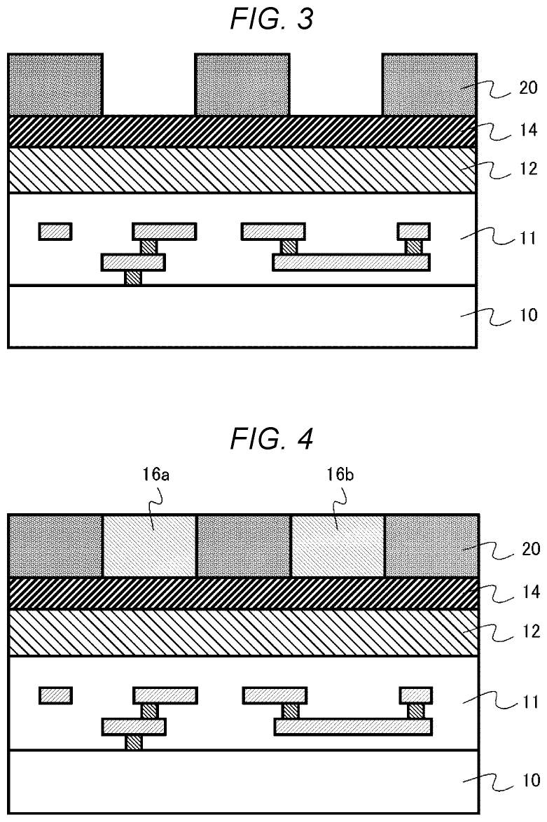

Next, a manufacturing method of the semiconductor device 100 of the embodiment will be described. FIGS. 2 to 5 are schematic cross-sectional views of the semiconductor device of the embodiment device in a manufacturing process.

The multilayer wiring layer 11 is formed on the silicon substrate 10 by using a known process technology. Next, the stacked structure including the silicon oxide layer 12 and the silicon nitride layer 14 is formed by, for example, a Chemical Vapor Deposition Method (CVD method), as shown in FIG. 2.

Next, a seed layer for plating (not illustrated) is formed on the silicon nitride layer 14. The seed layer is, for example, a stacked film including titanium and copper, which is formed by a known sputtering method. Next, a resist 20 is patterned by using a known lithography method, as shown in FIG. 3.

Next, the first copper wiring 16a and the second copper wiring 16b are respectively formed in openings of the resist 20 by a known electrolytic plating method, as shown in FIG. 4.

Next, the resist 20 is peeled off, and the seed layer remaining on the silicon nitride layer 14 is removed by a known etching method, as shown in FIG. 5.

Then, the polyimide film 18 is applied onto the first copper wiring 16a and the second copper wiring 16b. Thereafter, heat treatment is performed to cure the polyimide. Temperature of the heat treatment is, for example, 350° C.

The semiconductor device 100 of the embodiment in FIG. 1 is formed by the above manufacturing method.

Next, operation and effects of the semiconductor device of the embodiment will be described.

In a redistribution layer that is used for WL-CSP or the like, a thick metal wiring is used in order to reduce resistance. During heat treatment after formation of the thick metal wiring, thermal contraction of the metal wiring may occur simultaneously with thermal expansion thereof. A crack may occur in a protective resin film on an upper layer of the metal wiring due to stress caused by the thermal expansion and the thermal contraction of the metal wiring. Reliability of a semiconductor device is decreased when the crack occurs in the protective resin film.

For example, during the heat treatment for curing the polyimide film, the metal wiring is thermally contracted, applying tensile stress to surrounding polyimide films.

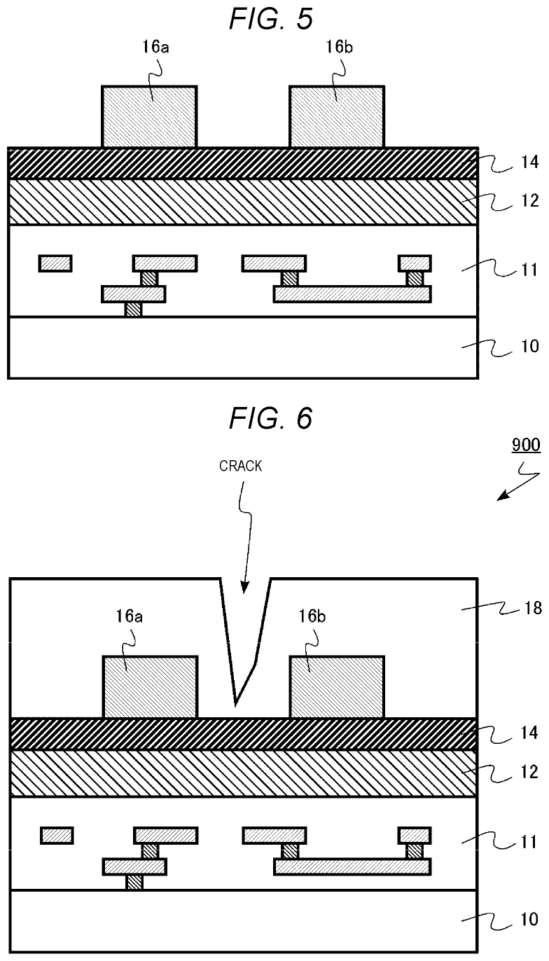

FIG. 6 is a schematic cross-sectional view of a semiconductor device 900 of a comparative example. The semiconductor device 900 of the comparative example is different from the semiconductor device 100 of the embodiment in that the film thickness of the polyimide film 18 is smaller than three times the film thickness of the first copper wiring 16a and the second copper wiring 16b.

In a case of the semiconductor device 900 of the comparative example, for example, during the heat treatment for curing the polyimide film, the first copper wiring 16a and the second copper wiring 16b are thermally contracted. Therefore, tensile stress is applied to the polyimide film 18 at a portion between the first copper wiring 16a and the second copper wiring 16b, causing the portion to crack.

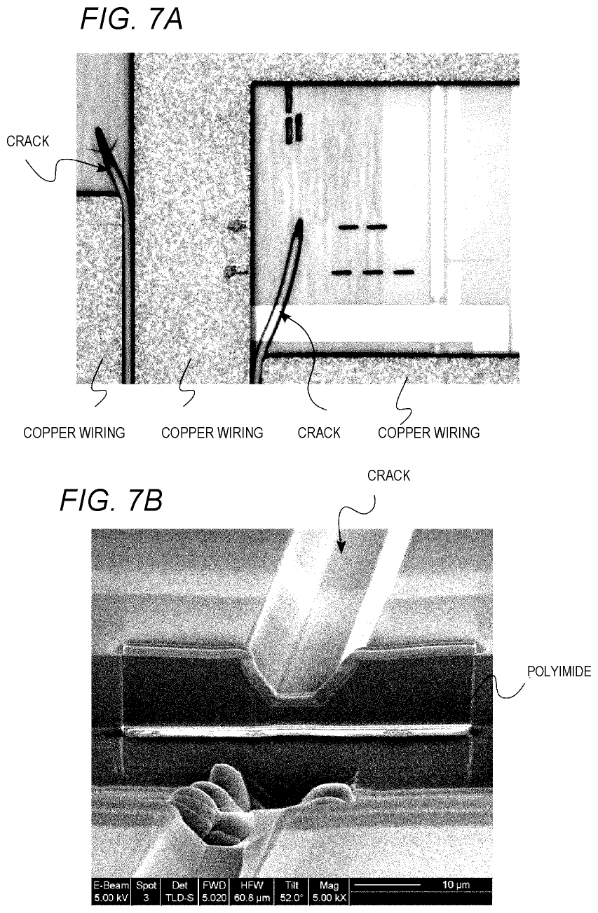

FIGS. 7A and 7B are photographs of cracks in the semiconductor device 900 of the comparative example. FIG. 7A is an optical microscope photograph in which cracks are photographed from an upper side of the polyimide film 18. FIG. 7B is a cross-sectional Scanning Electron Microscope (SEM) photograph of a crack. As is apparent from FIG. 7A, the cracks occur in narrow spaces between the copper wirings.

If a crack occurs in the polyimide film 18, for example, moisture may enter from this crack and corrode a wiring or the like, causing reliability failure.

In order to improve the performance of the semiconductor device 100, a redistribution layer with lower resistance is desired. Therefore, it is desirable to increase the film thicknesses of the copper wirings. In addition, it is desirable to narrow the intervals between the copper wirings in order to miniaturize the semiconductor device 100.

However, cracks are likely to occur since both film-thickening of the copper wirings and narrowing of the copper wiring intervals contribute to increased tensile stress applied to the polyimide film between the copper wirings.

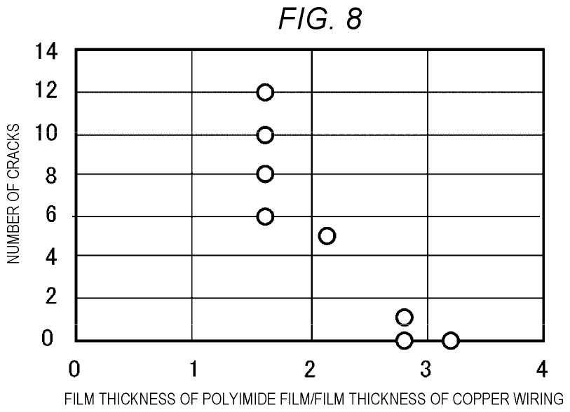

FIG. 8 is a diagram illustrating operation and effects of the semiconductor device of the embodiment. FIG. 8 is a graph showing results of the following observation. That is, samples were prepared with different ratios of the thickness of the polyimide film to that of the copper wiring, that is, with different t2/t1, and the number of cracks occurred after the samples were subjected to the heat treatment was observed by a microscope.

It is clear from FIG. 8 that the cracks were prevented when the film thickness of the polyimide film was approximately equal to or more than three times that of the copper wiring. When the ratio of the film thickness of the polyimide film to that of the copper wiring was 3.2 and the number of cracks occurred in a sample was 0, the film thickness of the copper wiring was 10 μm, and the film thickness of polyimide film was 32 μm.

In the semiconductor device 100 of the embodiment, the film thickness t2 of the polyimide film 18 is equal to or more than three times the film thickness t1 of the first copper wiring 16a and the second copper wiring 16b. Therefore, cracks in the polyimide film 18 are prevented from occurring. In the semiconductor device 100 of the embodiment, the film thickness t2 of the polyimide film 18 is equal to or more than 3.2 times the film thickness t1 of the first copper wiring 16a and the second copper wiring 16b.

In addition, cracks may occur in the multilayer wiring layer 11 and the silicon substrate 10 due to stress caused by the redistribution layer. In this case, for example, cracks are prevented from occurring by interposing the polyimide film between the redistribution layer and the underlying silicon nitride layer 14 as a buffer layer. However, when the polyimide film is provided between the redistribution layer and the underlying silicon nitride layer 14, the number of manufacturing processes and manufacturing costs of the semiconductor device increase.

In the semiconductor device 100 of the embodiment, since the film thickness t2 of the polyimide film 18 is made approximately equal to or more than three times the film thickness t1 of the first copper wiring 16a and the second copper wiring 16b, cracks can be prevented from occurring in the multilayer wiring layer 11 and the silicon substrate 10 without interposing the polyimide film between the redistribution layer and the underlying silicon nitride layer 14. That is, for example, even though the first copper wiring 16a and the second copper wiring 16b are directly in contact with the silicon nitride layer 14, cracks can be prevented from occurring in the multilayer wiring layer 11 and the silicon substrate 10.

From the viewpoint of improving the performance of the semiconductor device 100, it is desirable to increase the film thickness t1 of the first copper wiring 16a and the second copper wiring 16b to reduce resistance of the copper wirings. The film thickness t1 of the first copper wiring 16a and the second copper wiring 16b is preferably equal to or more than 5 μm, and is more preferably equal to or more than 10 μm. In the semiconductor device 100 of the embodiment, since the film thickness t2 of the polyimide film 18 is made equal to or more than three times the film thickness t1 of the first copper wiring 16a and the second copper wiring 16b, cracks of the polyimide film 18 are prevented even though the film thickness t1 of the first copper wiring 16a and the second copper wiring 16b is increased.

From the viewpoint of miniaturizing the semiconductor device 100, the interval between the first copper wiring 16a and the second copper wiring 16b is preferably narrowed. The interval between the first copper wiring 16a and the second copper wiring 16b is preferably equal to or less than 20 μm, and is more preferably equal to or less than 10 μm. In the semiconductor device 100 of the embodiment, since the film thickness t2 of the polyimide film 18 is equal to or more than three times the film thickness t1 of the first copper wiring 16a and the second copper wiring 16b, cracks of the polyimide film 18 are prevented even though the interval between the first copper wiring 16a and the second copper wiring 16b is narrowed.

From the viewpoint of improving the performance of the semiconductor device 100 and miniaturizing the semiconductor device 100, the film thickness t1 of the first copper wiring 16a and the second copper wiring 16b is preferably equal to or more than half of the interval between the first copper wiring 16a and the second copper wiring 16b, and is more preferably equal to or more than two-thirds of the interval. In the semiconductor device 100 of the embodiment, since the film thickness t2 of the polyimide film 18 is made approximately equal to or more than three times the film thickness t1 of the first copper wiring 16a and the second copper wiring 16b, cracks of the polyimide film 18 are prevented even though the ratio of the film thickness t1 of the first copper wiring 16a and the second copper wiring 16b to the interval between the first copper wiring 16a and the second copper wiring 16b is increased.

From the viewpoint of preventing cracks of the polyimide film 18, the film thickness t2 of the polyimide film 18 is preferably equal to or more than 30 μm, more preferably equal to or more than 40 μm, and still more preferably equal to or more than 50 μm.

As described above, according to the embodiment, the semiconductor device, in which cracks in the polyimide film 18 are prevented from occurring, is achieved. Therefore, the semiconductor device with improved reliability can be achieved.

Although the embodiment describes a case where the semiconductor substrate is a silicon substrate as an example, the semiconductor substrate may be a substrate other than the silicon substrate.

Although the embodiment describes a case where the first metal wiring and the second metal wiring are copper wirings as an example, materials of the first metal wiring and the second metal wiring may be other materials, for example, aluminum or an aluminum alloy.

Although the embodiment describes a case where the resin film is a polyimide film as an example, the resin film may be a film formed of other materials. In addition, in a case where the polyimide film is interposed between the redistribution layer and the underlying silicon nitride layer, the margin for preventing cracks in the multilayer wiring layer and the silicon substrate from occurring is further improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. For example, an element of an embodiment may be substituted by another element of another embodiment or may be changed. The accompanying claims and their equivalents are intended to cover such forms or modifications as would fall within the scope and spirit of the inventions.

What is claimed is:

1. A semiconductor device comprising:
a semiconductor substrate;
a multilayer wiring layer on the semiconductor substrate;
an insulation layer above the multilayer wiring layer;
first and second metal wirings on the insulation layer; and
a resin film that covers the insulation layer and the first second metal wirings, wherein
the resin film has a thickness about three times a thickness of the first and second metal wirings in a direction perpendicular to the semiconductor substrate, and
a thickness of each of the first and second metal wirings is greater than a thickness of a wiring included in the multilayer wiring layer.

2. The semiconductor device according to claim 1, wherein
the thickness of the resin film is equal to or more than three times the thickness of the first and second metal wirings.

3. The semiconductor device according to claim 1, wherein
the first and second metal wirings contain copper.

4. The semiconductor device according to claim 1, wherein
the resin film is a polyimide film.

5. The semiconductor device according to claim 1, wherein
the thickness of the first and second metal wirings is equal to or more than half of an interval between the first and second metal wirings on the insulation layer.

6. The semiconductor device according to claim 1, wherein
the thickness of the first and second metal wirings is equal to or more than 5 μm.

7. The semiconductor device according to claim 1, wherein
the thickness of the resin film is equal to or more than 30 μm.

8. The semiconductor device according to claim 1, wherein
the insulation layer contains silicon nitride.

9. The semiconductor device according to claim 1, wherein:
the multilayer wiring layer includes a plurality of metal wirings.

10. The semiconductor device according to claim 9, further comprising:
a silicon oxide layer between the insulation layer and the multilayer wiring layer.

11. A method of manufacturing a semiconductor device, comprising:
forming a multilayer wiring layer on a semiconductor substrate;
forming an insulation layer above the multilayer wiring layer;
forming a resist having openings on the insulation layer;
forming first and second wirings in the openings of the resist;
removing the resist; and
applying a resin film to cover the insulation layer and the first and second wirings, wherein
the resin film has a thickness about three times a thickness of the first and second metal wirings in a direction perpendicular to the semiconductor substrate, and
a thickness of each of the first and second metal wirings is greater than a thickness of a wiring included in the multilayer wiring layer.

12. The method according to claim 11, wherein
the thickness of the resin film is equal to or more than three times the thickness of the first and second metal wirings.

13. The method according to claim 11, wherein
the first and second metal wirings contain copper.

14. The method according to claim 11, wherein
the resin film is a polyimide film.

15. The method according to claim 11, wherein
the thickness of the first and second metal wirings is equal to or more than half of an interval between the first and second metal wirings on the insulation layer.

16. The method according to claim 11, wherein
the thickness of the first and second metal wirings is equal to or more than 5 μm.

17. The method according to claim 11, wherein
the thickness of the resin film is equal to or more than 30 μm.

18. The method according to claim 11, wherein
the insulation layer contains silicon nitride.

19. The method according to claim 11, wherein
the multilayer wiring layer includes a plurality of metal wirings.

20. The method according to claim 19, further comprising:
forming a silicon oxide layer between the insulation layer and the multilayer wiring layer.
